(19) United States
(12) Patent Application Publication
(10) Pub. No.: US 2011/0264295 A1
(43) Pub. Date: Oct. 27, 2011

(54) REMOTE UTILITY METERING USING A PASSIVE OPTICAL NETWORK

(76) Inventor: Peter Schmelcher, Delta (CA)

(21) Appl. No.: 12/992,499

(22) PCT Filed: May 30, 2008
(86) PCT No.: PCT/CA08/01056

§ 371 Date: Nov. 12, 2010

(30) Foreign Application Priority Data
May 14, 2008 (CA) 2630633

(51) Int. Cl. G08C 23/06; H04B 10/20; H05K 13/00; G06F 1/28

(52) U.S. Cl. 700/295; 700/297; 340/870.28; 340/870.02; 29/592.1

(57) ABSTRACT

A single fiber passive optical network architecture provides utility metering and control functions for residential and commercial customers. A module provides customer termination of the network, the module either replacing or retrofitting to an existing electrical power wall box. This allows the module to not only support communications functions but to use such functions to remote monitor commodity utilities used by the customer.

### FIELD OF THE INVENTION

This invention relates to remote utility metering using a passive optical network. The invention further relates to the integration of utility meter data and control information with customer voice, video, and data services through a two-way passive optical network that is terminated in an electric power meter box.

### BACKGROUND OF THE INVENTION

The suppliers of electric power, gas, water and other such metered consumable utilities most typically determine a subscriber's consumption by sending a service person to each meter location to manually record the information displayed on the meter dial. However, it is often difficult for the service person to access the meter for reading, inspection and maintenance. When access to a meter is not possible, billings are made on the basis of estimated readings. These estimated billings often lead to customer complaints and the process has been time consuming, inaccurate, and expensive.

In recent years many attempts have been made, largely by power utilities, to develop automated remote metering wherein a transducer unit with dedicated communications capability is used with the meters to detect the output of such meters and transmit that utility's meter information back to the utility. Such units are dedicated to a particular utility.

In the prior art, various automatic meter readers have been proposed, such as U.S. Pat. No. 5,880,464, in which infrared light sensors are used to detect the shadow of a meter pointer against a meter face to enable the meter reader to determine consumption rates. In this instance, the device is placed on the cover of a watt-hour meter. While this provides a means to measure power consumption without altering or entering the basic meter, no mention is made of the means for conveying the information to the utility provider, nor is there any provision for other services, such as video.

A further example of such a system is described by Lumsden in U.S. Pat. No. 3,922,492. This patent describes a system for remotely reading, storing and transmitting the reading of a power meter to a central computer. The computer automatically sends a signal by telephone to interrogate the meter which is fitted with a transponder.

U.S. Pat. No. 4,035,772 issued to Takeshi teaches a system in which a central computer terminal is connected to a series of remote computer terminals which have previously stored the meter readings. In Takeshi, the terminals replace the transponders of the Lumsden invention, but there is no provision for other than electric power consumption information.

U.S. Pat. No. 4,394,540 issued to Willis uses a coded signal over the telephone network to interrogate a meter reader. This system involves a microprocessor as the meter reader, a telephone isolation device, a call answering device, various detection devices, a data transmitter and a modem.

U.S. Pat. No. 5,140,351 issued to Garcia uses a coherent fiber optic link which provides a visual representation of each digit of the meter. The visual image is then transferred to a central receiving location.

U.S. Pat. No. 5,161,182 issued to Merriam discloses a system in which utility computers are coupled by modems to the individual sites which have meter sending units. Each meter sending unit has a microprocessor which counts the pulses emitted for each unit consumption of power and stores this count in RAM. This count is transformed into a tone which is transmitted over the phone lines to the central computer.

A wireless telemetry system to provide real time reading and control of meters using the existing wireless networks connecting meter transmitting units and central receiver units is disclosed in U.S. Pat. No. 5,748,104 issued to Argyroudis. In the described embodiment, the remote metering unit is a basic transceiver coupled to a pre-existing conventional electromechanical utility meter by an interface device.

U.S. Pat. No. 5,808,558 issued to Meek describes a universal data gathering system that can interact with different types of operating systems. It consists of three elements. The first element is a universal transponder which accumulates the data, the second element is a meter interface unit which connects the transponder to the data gathering system, and the third element is a universal data reader. Each part of the system can be polled by any remote unit which responds with the appropriate protocol. This invention hopes to overcome the diverse operating protocols used by different meter companies.

U.S. Pat. No. 5,852,658 issued to Knight describes a remote automatic monitoring and recording system which comprises an electronic meter reader, a data module, a telephone interface, a billing computer and a telephone modem. In this, three telephone lines are required to operate the system.

U.S. Pat. No. 5,767,790 issued to Jovellana also describes an automatic utility meter reader and monitor for electric, gas and water. This invention provides communication from the utility to the meter unit using a standard computer modem link which transmits commands from the utility to the meter reading system. The automatic meter unit has a compiler for interpreting commands from the host computer unit.

U.S. Pat. No. 5,751,797 issued to Saadeh uses a plurality of computer modems connected to a single computer and to a series of automatic meter reading devices. The single computer sequentially polls each meter reading device using the appropriate modem link. This link allows the system to send control data to the meter reading devices and also allows the meter reading devices to send data back to the central computer.

A number of prior art patents utilize wireless means to convey consumable utility usage data, especially electrical power, but none have done so over the same communication channel as is also used to deliver a plurality communication services such as a combination of other utility usage data, telephony, internet, and wideband video.

U.S. Pat. No. 7,289,887 issued to Rodgers provides for remote electronic meter reading by means of a LAN utilizing 802.11 or 802.15.4. However, it is limited to narrow band bi-directional wireless, and is not capable of providing for the carriage of entertainment video.

U.S. Pat. No. 7,250,874 issued to Mueller et al. uses wireless to communicate utility usage data, but does not provide the multiplicity of two way services described in this present disclosure. Similarly, U.S. Pat. No. 7,182,632 issued to Johnson Jr. et al. describes a means of electronically accessing metering information, but does not describe the means for communicating said information to a utility service provider.

In addition, U.S. Pat. No. 7,263,450 issued to Hunter describes a means for the optical reading of a meter, but does not address the combined transmission of communication services, such as video.

Several companies have developed the technology and devices that allow the energy meter to be read remotely. Most devices read the meter remotely and then transmit the signal either by hardwire, by public telephone, by wireless system, by cellular phone and even by the power transmission wire itself.

As the present invention also involves the use of a passive optical network (“PON”), some background on passive optical networks is provided herein.

A passive optical network (PON) is a point-to-multipoint, fiber to the premises network architecture in which unpowered optical splitters can be used to enable a single optical fiber to serve multiple premises. A PON configuration reduces the amount of fiber and central office equipment required compared with point to point architectures.

Downstream signals are broadcast to each premise sharing a fiber. Upstream signals are combined using a multiple access protocol, usually time division multiple access (TDMA). A PON takes advantage of wavelength division multiplexing (WDM), using one wavelength for downstream traffic and another for upstream traffic on a single nonzero dispersion shifted fibre. In one embodiment, downstream traffic is transmitted on the 1490 nanometer (nm) wavelength and upstream traffic at 1310 nm. The 1550 nm band is allocated for optional overlay services, typically RF (analog) video.

A PON is a converged network in that all of these services are typically converted and encapsulated in a single packet type for transmission over the PON fiber. For example, BPON is ATM-based, whereas EPON is Ethernet-based. Although GPON allows for a mix of TDM, ATM and GEM mode, GEM (GPON Encapsulation Method, a variant of Generic Framing Procedure or GFP) is the usual transport mechanism.

A PON is a shared network, in that the central station sends a single stream of downstream traffic that is seen by all receivers. Each receiver only reads the content of those packets that are addressed to it. Encryption is used to prevent eavesdropping on downstream traffic.

It will be appreciated that none of the prior art discloses a system using a PON architecture for integrating remote metering with other customer communication-based services in an easily retrofittable system associated with the power meter wall box of a customer.

### SUMMARY OF THE INVENTION

The invention provides a fully integrated electro/optical service that either replaces or retrofits onto or into existing electrical power meter wall boxes and is compatible with current consumable utility operations.

A customer utilities interface module provides customer termination of a passive optical network. The module may be configured so as to incorporate the power utility meter functions and is located in the pre-existing electrical power meter wall box and or it may be provided as an expansion module for the conventional power meter wall box.

The module is adapted to communicate customer utility usage data and information to a utility over the passive optical network. A single optical fiber cable enters the electric meter wall box through a connector located on the power meter wall box or on an extender ring associated with the wall box. It can also be located on a housing used to replace the conventional meter wall box.

A companion unit is located at the utility supplier's premises or at a convenient remote location to receive utility usage data and information from the remote customer module, and to transmit control information to the customer module. This received and transmitted information is in optical form to and from the passive optical network. An electro/optical transducer is located in the companion unit. The signals are parsed such that only the required signals are routed to and from the other utility suppliers that are being serviced by the companion unit and the customer module.

While telephone service has long been considered a utility, in the last few decades other communications services such as broadband services and possibly wireless, have also effectively become ubiquitous enough to be considered utilities. In this disclosure and in the claims, the term “utilities” encompasses consumable utilities such as electric power, gas, water and possibly sewage disposal, as well as communications supplied services such as telephone, CATV, broadband and can include wireless when to customer premises. The term “non-communication utilities” refers to consumable utilities such as electric power, gas and water that do not deliver communications services to the customer.

In one aspect, the invention comprises a customer utilities interface apparatus comprising a module associated with customer premises that is adapted to receive utility information relating to the delivery of a non-communication utility to customer premises and to communicate that information over a passive optical network. The apparatus can also receive control information from a remote source over the passive optical network.

In a more specific aspect, the customer utilities interface apparatus comprises an optical fiber transducer and a network element for facilitating communication with a passive optical network. At least one interface element accommodates an electromagnetic signal associated with a non-communication metered utility supplied to the customer premises and the signal is adapted and conditioned for transmission over the passive optical network. A plurality of interface elements allows the apparatus to agglomerate the signals from various utilities at the customer premises and to transmit them over the passive optical network.

In another aspect, the invention comprises a method of installing the customer utilities interface apparatus whereby the existing wall box is detached from its associated power cable, and is replaced with the apparatus that includes a suitable housing attachable to the power cable, a power meter and a conventional cover.

An alternative method according to the invention is to disconnect the cover from the existing meter base and to connect the apparatus as an extender housing to the connection means previously used for the cover, then securing the cover to the end of the extender housing.

According to yet another method, the cover is removed from the existing meter base, and connecting to the meter base an apparatus that includes a conventional power meter display and a cover in addition to the elements of the invention.

The scope of the invention includes the overall system by which multiple commodities at each of a plurality of customer premises are metered over a passive optical network. The PON provides a communication facility between modules at the customer premises and a hub module. Each has an optical fiber transducer for connecting them to the PON and network elements for facilitating communication with one another over the PON.

In another aspect, a utilities servicing module comprises an optical fiber transducer, at least one network element for facilitating communication over the PON. The utilities servicing module is adapted to parse said electrical signals into information relating to utilities used by each of a plurality of customer premises and to communicate that information to at least one utility supplier.

Other aspects of the invention will be appreciated by reference to the detailed description of the embodiments of the invention and to the claims.

### BRIEF DESCRIPTION OF THE DRAWINGS

The preferred embodiment of the invention will be described by reference to the drawings thereof, in which:

FIG. 1 is an overview block diagram of the system of the present invention in accordance with the preferred embodiment;

FIG. 2 is a block diagram of a utilities servicing module located at a commodity provider's premises;

FIG. 3 is a block diagram of the remote customer utilities interface module at the customer premises;

FIG. 4 is a cross-sectional schematic of a customer utilities interface module according to the invention using a conventional glass cover;

FIG. 5 is a cross-sectional schematic of a customer utilities interface module using an expander ring;

FIG. 6 is a cross-sectional schematic of a customer utilities interface module using an integral weatherproof cover;

FIG. 7 is an exploded view of one embodiment of a customer utilities interface module;

FIG. 8 is a view of an improved anti tamper sealing ring according to the invention; and,

FIG. 9 is a detailed view of the mating portions of the improved anti tamper sealing ring.

### DETAILED DESCRIPTION OF THE PREFERRED EMBODIMENT

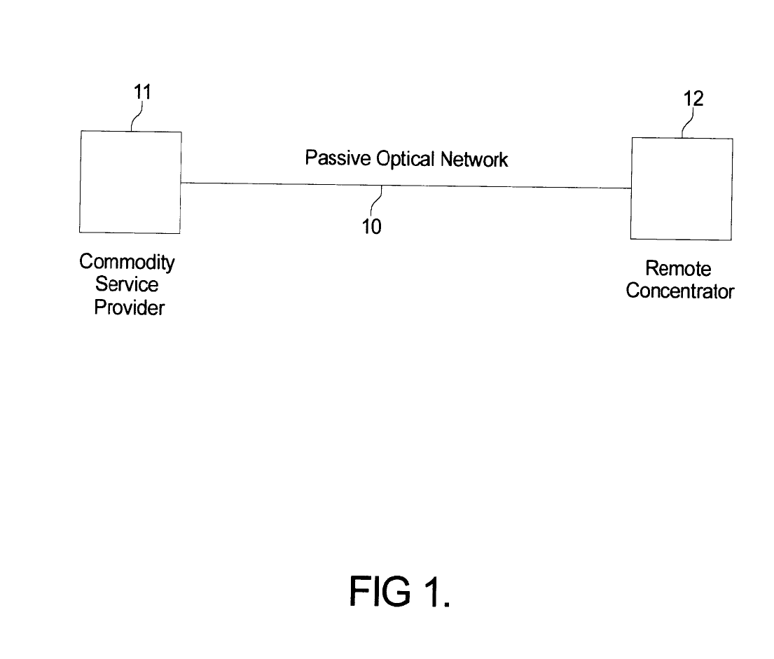

FIG. 1 is a block diagram of an integrated passive optical network system for the conveyance, measuring and control of a multiplicity of consumable utility metering and control services and communications services according to the preferred embodiment. A passive optical network fiber 10 connects the utility supplier 11 to a remote customer utilities interface module 12, the remote module 12 acting as a customer premises termination for the passive optical network.

The customer module 12 is used to convey the usual communication services typically provided over a passive optical network, such as telephone, CATV and broadband but also conveys non-communication utility meter data and control information. For example, in the case of the electric power utility, the module 12 interacts with the utility supplier 11 to exchange measuring, monitoring, and control information by means of passive optical network fiber 10. In such case, the information transmitted and received over PON fiber 10 may include measurement of electric power delivered to the customer premises, monitoring of the status of the electrical parameters at a remote location, and bi-directional control of the flow of electrical power to the remote location, for example to effect electrical power load shedding, reduction of utility service, increase in utility service or disconnection of the utility from the customer premises.

Remote module 12 can also provide for bidirectional control, measurement and monitoring of other utility suppliers' services (water, gas, etc.) by means of appropriate routing and terminal facilities provided in the remote module 12 and in the utility supplier hub 11, as will be described below.

As will also be detailed below, the module 12 is preferably physically located at the wall-mounted electrical power meter wall box and is powered by the power supplied to the premises through the electric power meter wall box.

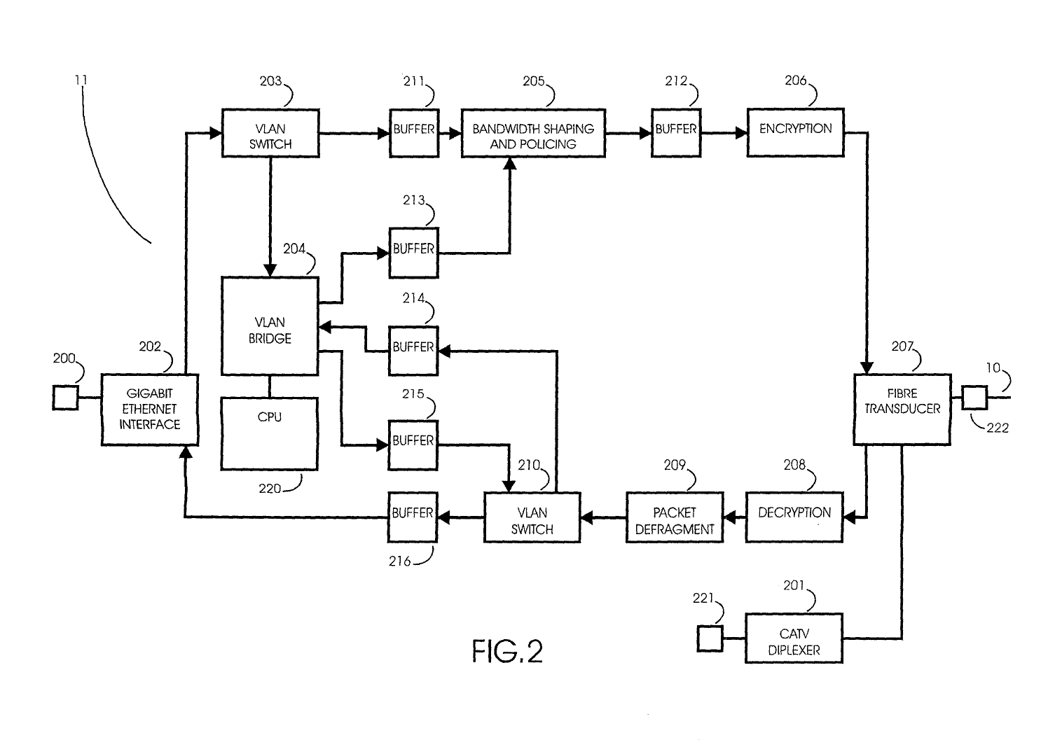

FIG. 2 is a block diagram of module 11 located at a utility supplier's premises or at some other convenient hub. Hub module 11 includes various network elements as described below to facilitate communication between the module 11 and the passive optical network. Ethernet connector 200 connects module 11 to multiple utility suppliers each of which is assigned a unique VLAN identifier to facilitate the separation and isolation of packets. Block 202 conditions and converts the Ethernet physical interface signals. VLAN switch 203 separates received packets according to VLAN. Monitoring, management and configuration packets are VLAN bridged by VLAN bridge 204 to the remote CPU in module 12 (via buffer 213 and ultimately to transducer 207 and onto fiber 10) or the local CPU 220. Buffers 211-216 permit multiple unsynchronized clocks within module 11. VLAN packets transmitted to module 12 are bandwidth shaped and policed in bandwidth shaping and policing block 205 which can add delay or destroy packets to limit the peak data rate to each remote module 12. Packets are encrypted in encryption block 206 and converted to light in transducer 207 and transmitted over fiber 10 attached with connector 222.

Received optical signals from fiber 10 are converted to electrical signals in 207 and unencrypted in 208 and defragmented, if required, in 209. VLAN switch 210 separates packets by VLAN to Ethernet signal conditioner 202 or VLAN Bridge 204. Packets are VLAN bridged to CPU 220 or Ethernet interface 202 via VLAN switch 210.

VLAN Bridge 204 receives and transmits VLAN packets for CPL 220 over fiber 10 or Ethernet connector 200.

CATV diplexer 201 filters the CATV signal from connector 221 into upstream and downstream frequency bands. Signals from 201 connect to fiber transducer 207 which modulates the analog optical downstream wavelength and demodulates the analog optical upstream wavelength in fiber 10. Fiber 10 has four optical wavelengths; two for digital communication and two for CATV communication.

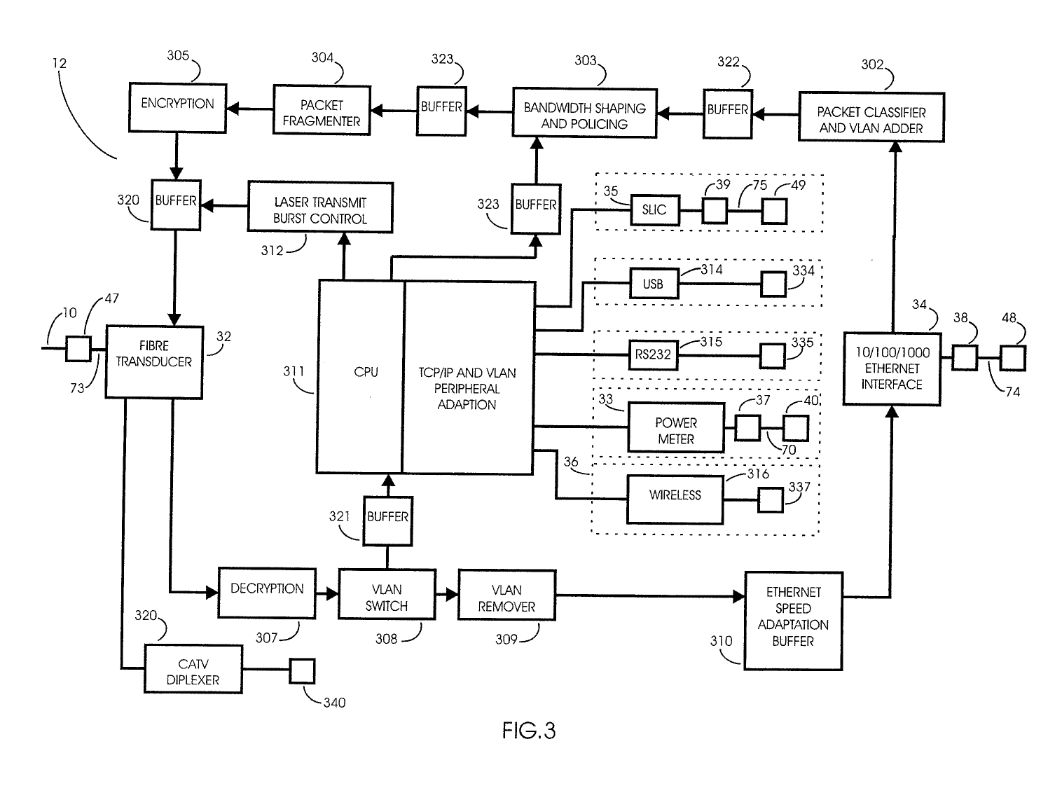

FIG. 3 is a block diagram of module 12 located at the customer's premises. As will be described below, module 12 includes various networks elements adapting the module to communication over the passive optical network, various interface elements for interfacing module 12 with electromagnetic signals associated with various utilities used by the customer premises, and means for processing the signals, and for conditioning, aggregating and transmitting the electromagnetic signals over the passive optical network. It also includes means for parsing incoming signals using VLAN coding into the information intended for the individual utility interfaces associated with module 12

Customer broadband Ethernet interface connector 48 connects to Ethernet signal conditioner 34 which conditions and converts the Ethernet physical interface signals. Customer broadband data packets are classified for transmit priority and a VLAN is added in 302. Bandwidth shaping and policing 303 can add delay or destroy packets to limit the peak data rate. Packets are assembled into data blocks where a packet can be fragmented spanning two optical transmit data bursts in 304. Transmit blocks are encrypted in encryption block 305 and buffered in buffer 320. The PON burst controller 312 commanded by remote module 12 sends data bursts to transducer 32 that optically bursts the data over fiber 10. Buffers 321, 322, 323 permit multiple unsynchronized clocks within module 12.

Optical signals received from fiber 10 are converted to electrical signals in 32. Packets are decrypted in 307. VLAN switch 308 forwards management packets and packets with data for peripheral interface or metering devices 33, 35, 36, 314, 315 to CPU 311, and customer broadband Ethernet packets to VLAN remover 309. Ethernet speed adaptation buffer 310 stores the received packet if slower data rates are used by the customer over the broadband Ethernet interface connector 48. Ethernet interface 34 electrically conditions and converts the data into signals for the Ethernet interface connector 48. CPU 311 executes software drivers to adapt the peripheral signal conditioner data to and from TCP/IP using a different VLAN for each interface.

The outputs of the signal interface adapters, signal processors or measuring devices 33, 34, 35, 314, 315, 316 are provided at output terminals 37, 48, 49, 334, 335, or antenna 337, each output terminal being dedicated to a particular service at the customer premises. According to the invention, such services include at least one non-communication commodity utility, for example electrical power, natural gas, water, etc. As each service operates under different signal conditions, the signal conditioners 33, 34, 35, 314, 315, 316 will each be configured to condition the signal 37, 48, 49, 334, 335 or antenna 337 to suit the particular service for which it is intended. For example, element 35 may be an off-the-shelf SLIC chip used to convert VOIP to telephony signal standards, and element 314 may be an off-the-shelf root hub adapter for USB devices.

Signal interface elements and conditioning components 33, 34, 35, 314, 315, 316 are each associated with respective terminals 37, 48, 49, 334, 335, or antenna 337, which also act as interface elements, and they are otherwise connected to appropriate slots on a motherboard 30 that houses the electronics of FIG. 3. TCP/IP and VLAN peripheral adaptation software in CPU 311 detects the addition or removal of a peripheral module and reconfigures the VLAN tables and TDMA control parameters accordingly. This allows modular expandability of the ranges of commodity services supported by the module 12.

CATV diplexer 320 filters the CATV connector 340 into upstream and downstream frequency bands. Signals from 320 connect to fiber transducer 32 which modulates the analog optical upstream wavelength and demodulates the analog optical downstream wavelength in fiber 10.

The PON fiber 10 is connected to an electro/optical fiber transducer 32, simply referred to herein as an optical transducer. Transducer 32 operates in a bidirectional mode, accepts outgoing electrical signals and converts them into optical signals which can be transmitted over PON fiber 10. Conversely, optical signals entering utility supplier 11 from PON fiber 10 are converted into electrical signals by means of transducer 207.

In the preferred embodiment, the electronics for implementing the functionality described above are housed on a motherboard 30 to which power is supplied through an uninterruptible power supply 31. UPS 31 draws power from the pre-existing power control module 40 associated with the customer's power meter wall box. The PON fiber 10 is connected to bidirectional electro/optical transducer 32 located on motherboard 30.

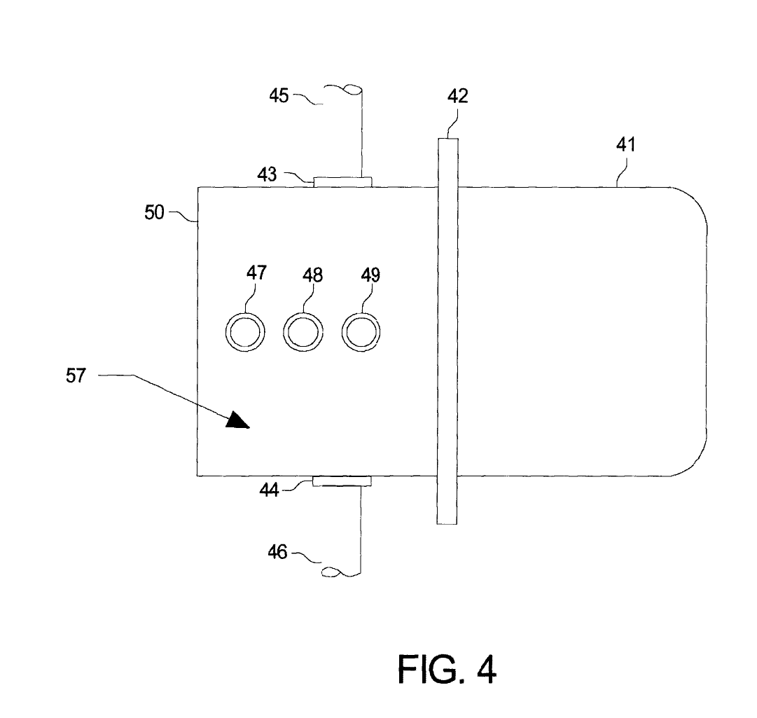

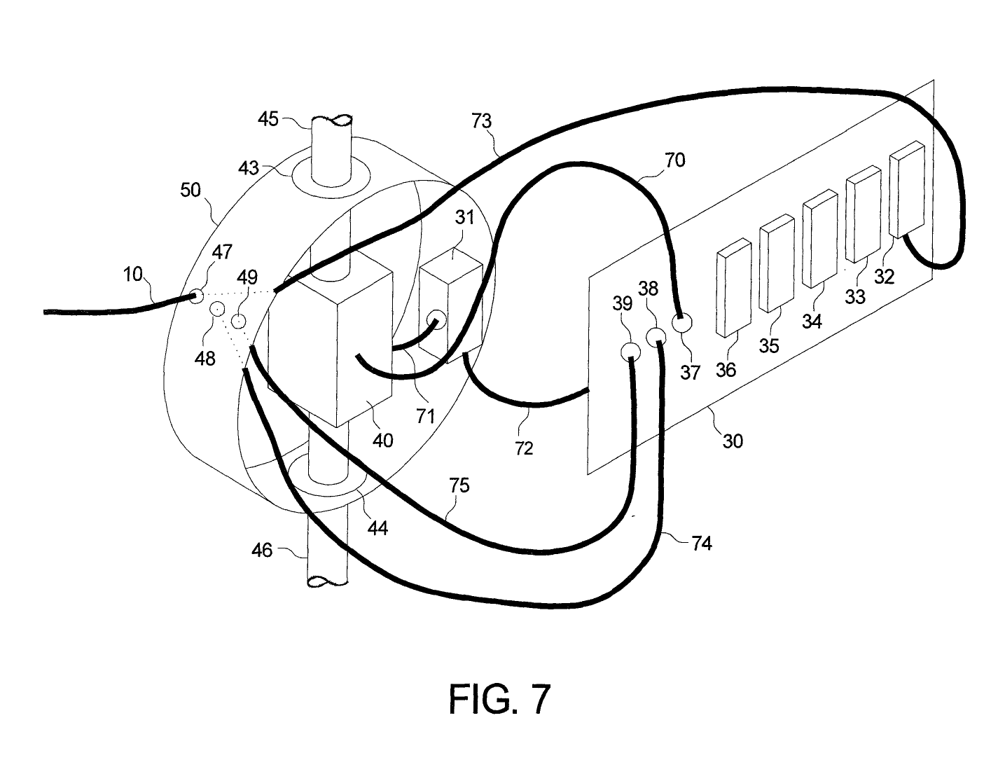

FIG. 4 illustrates a wall box 57 according to one embodiment of the invention that is designed to replace a conventional electric power meter wall box. As in the conventional case, the wall box 57 is mounted on a wall at the customer premises and includes an opaque, usually metal, housing 50 (also called a meter base), a glass cover 41 and a sealing ring 42. The weatherproof entrance and exit fittings 43 and 44 respectively, and the entrance and exit electrical cables 45 and 46 respectively are examples of the existing art, and are included herein for purposes of clarity only. Weatherproof fiber optic connector terminal 47 permits connection for the PON fiber 10 of FIG. 1. Connectors 48 and 49 are weatherproof terminals for providing connection to other utility suppliers' measuring, monitoring and control systems, and/or other services such as video, telephony, or data. The service types are not limited to the aforementioned, and any form of signal may be accommodated by an appropriate terminal connector. For simplicity of illustration, only two such connectors have been shown. In practice, any number can be accommodated. While connectors 47, 48 and 49 are shown located on the side of electric wall box housing 57, any location on the wall box can be used, including circumferential displacement around the wall box. As is illustrated in FIG. 7, the wall box housing or meter base 50 includes therein the motherboard 30 containing the electronics needed to implement the invention.

The apparatus of FIG. 4 replaces the pre-existing conventional electric power wall box that is attached to a power cable supplying power to the customer premises. The conventional wall box includes a power meter base and a cover. The pre-existing wall box is detached from the power cable and is replaced with the apparatus of FIG. 4 that is adapted to attach to the power cable 45, 46.

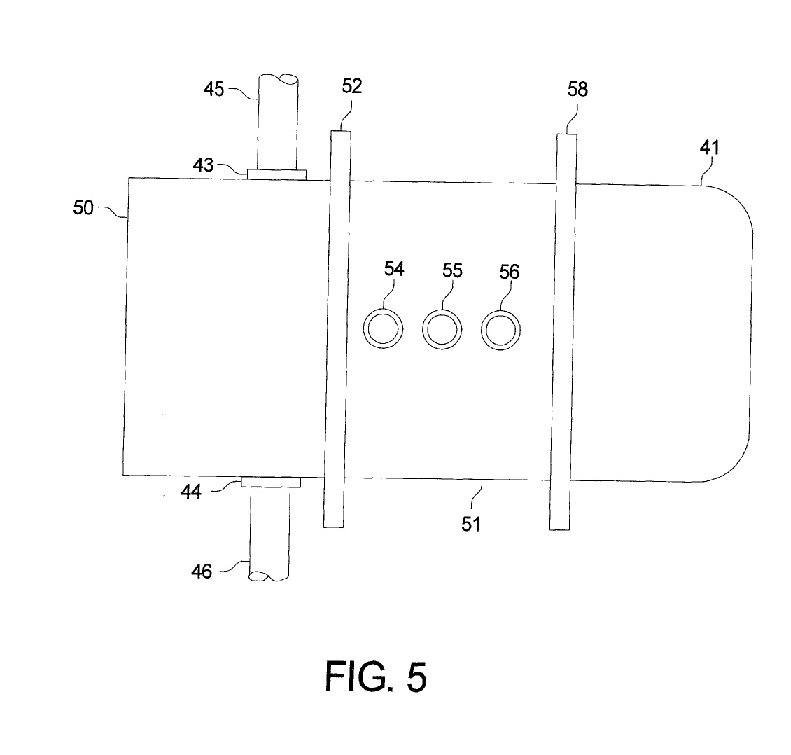

FIG. 5 illustrates the components of a conventional power meter wall box on which an expander module (51 and 52) has been retrofitted in accordance with the preferred embodiment of the invention. The conventional power meter wall box includes metal housing or meter base 50, sealing ring 58 and glass cover 41 housing the original power meter. The glass cover 41 is typically secured to the meter base 50 by the sealing ring 58 in conjunction with connection means such as threads for screwing the cover onto the base. The weatherproof entrance and exit fittings 43 and 44 respectively, and the entrance and exit electrical cables 45 and 46 respectively are examples of the existing art, and are included herein for purposes of clarity only. Expander housing 51 and associated sealing ring 52 are added between the wall box housing 50 and the original power meter housed within glass cover 41, with motherboard 30 and associated terminals 37, 48, 49, 334, 335 and antenna 337 (see FIG. 3) being housed within expander housing 51, but that are not shown in FIG. 5. In a typical case, the expander housing 51 is screwed to the threads normally used to connect the cover 41 to the base 50. Weatherproof fiber optic connector 54, mounted on expander housing 51 provides connection to the PON fiber 10. Connectors 55 and 56, also located on expander housing 51 are weatherproof electrical connectors for providing connection to other utility suppliers' measuring, monitoring and control systems as discussed above.

The expander module 51, 52 is installed by disconnecting the connection means (unscrewing the cover from the base), and removing the cover 41 from the power meter base 50. The expander housing is then screwed to the base 50 and the cover 41 is attached to an end of the housing that similarly includes connection means such as threads corresponding to the connection means on the conventional base 50.

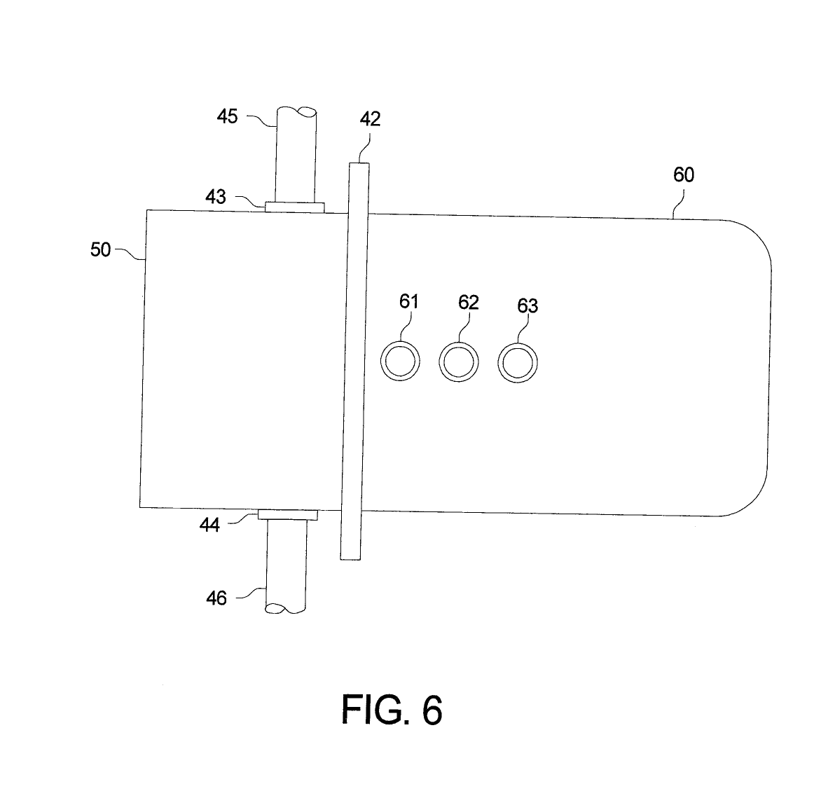

FIG. 6 shows yet another physical realization of a housing for the remote module 12 wherein the original sealing ring and glass cover are discarded and replaced with a sealing ring 42 and a new glass cover 60 in which are housed the motherboard 30, terminals 37, 48, 49, 334, 335, and antenna 337 and optionally, conventional power meter readings displays, but that are not shown in FIG. 6. Weatherproof fiber optic connector terminal 61, mounted on weatherproof housing 60 provides for connection to the PON fiber 10. Connectors 62 and 63, also located on weatherproof housing 60 are weatherproof electrical connectors for providing connection to other utility suppliers' measuring, monitoring and control systems.

FIG. 7 shows an exploded view of remote module 12 by reference to the embodiment of FIG. 4 where the pre-existing power meter wall box is replaced with a wall box according to the invention. Entrance cable 45 and exit cable 46 pass through entrance and exit fittings 43 and 44 respectively, located on wall box housing 50 and are connected to electric power control module 40. Motherboard 30 is housed in housing 50. In actual deployment, motherboard 30 is preferably secured by means of mounting brackets, which are not shown herein for reasons of clarity. Various mounting means may be employed without departing from the objects of this invention.

Cable 70 is used to provide transfer of information between power service module 33 and electric power control module 40 by means of electrical connector 37. This information is the voltage and current signal used to calculate the electrical energy consumed by the customer. An option to disconnect power to or from a customer is an electromechanical switch or relay mounted inside module 40 and activated by module 33. AC power cable 71 provides AC supply for uninterruptible power supply 31. Power cable 72 provides DC power to the motherboard 30 from uninterruptible power supply 31.

PON fiber 10 enters wall box housing 50 by means of weatherproof fiber optic connector 47 and is routed to electro/optical transducer 32 by means of fiber optic cable 73. Cables 74 and 75 are used to exchange utility supplier information, and other forms of information, such as telephony, video, internet and data from modules 34 and 35 via motherboard connectors 38 and 39. For clarity only two are shown, which are connected to weatherproof electrical connectors 48 and 49. Wireless module 36 contains both the electronics 316 and antenna 337.

Referring to FIG. 7 and FIG. 1, it will be appreciated that disconnecting PON fiber 10 from fiber optic connector 47 will cause a break in the continuity of the connection between utility supplier 11 and remote module 12. Since PON fiber 10 provides bidirectional communications between utility supplier 11 and remote module 12, any such interruption will be immediately detected at utility supplier 11. This will result in an alarm, and appropriate action can be taken, such as dispatching service personnel to investigate the nature of said interruption.

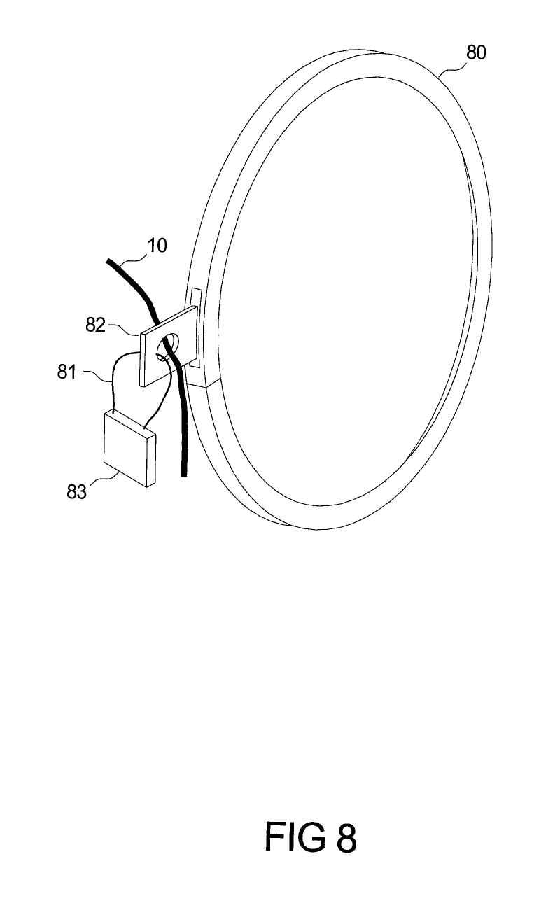

This means of detecting a break in the continuity of communication as an alarm indication can be further exploited to provide an alarm in the event that an attempt is made to remove any or all of the sealing rings depicted in FIG. 4, FIG. 5, and FIG. 6 which sometimes occurs during unauthorized tampering with the power meter readings. FIG. 8 depicts an improved sealing ring arrangement 80. Save for the fiber 10 being threaded through the opening 82, FIG. 8 depicts prior art. A loop of wire 81 passes through opening 82, and is secured by means of seal 83. If wire 81 is cut or severed, this can be detected by service personnel visiting the site. According to the present invention, PON fiber 10 of FIG. 1 is also routed through opening 82 such that sealing ring 80 cannot be opened or removed without first removing PON fiber 10, effectively severing or disconnecting it. In this manner further security is provided to any of the remote housings described in this invention. An attempt to camouflage the opening of the wall box by reinstalling a fresh seal loop will be detected by the loss of signal from fiber 10 when the original seal loop and the fiber are cut or unplugged to gain access to the wall box.

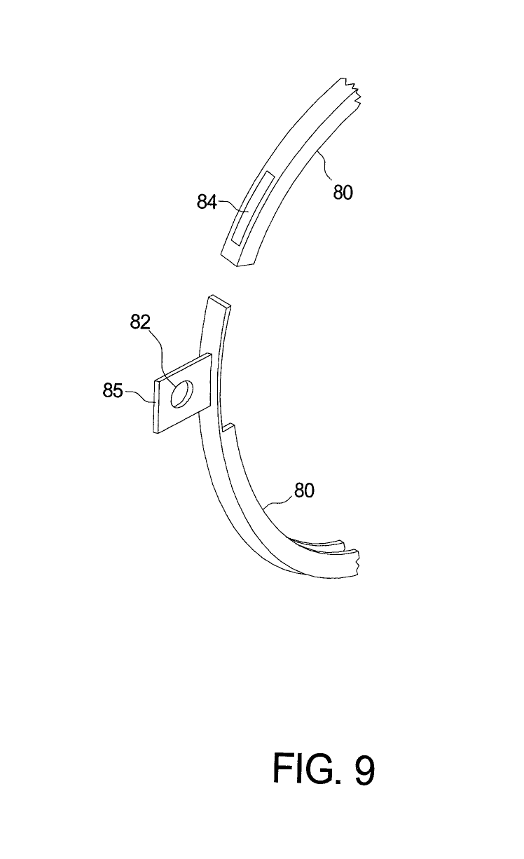

Further details of the sealing ring of the prior art are illustrated in FIG. 9. It can be seen in FIG. 9 that one mating portion of improved sealing ring 80 is equipped with a slot 84 through which bendable tongue 85 on other mating portion of improved sealing ring 80 must pass in order to close improved sealing ring 80.

In accordance with the objects of this invention, improved sealing ring 80 can be used to replace sealing rings 42, 52, and 58.

In the preceding illustrative examples, one type of North American wall box and meter assembly has been depicted. Other types of assemblies may be utilized without departing from the claims of this invention.

It is also contemplated that a customer interface module may be designed to service a number of customers in close proximity to one another in which case the module 12 may be physically mounted on a power pole or such structure in a neighbourhood, or in an underground power box. In such cases, it will be appreciated that the single-customer wall-box embodiment described in the preferred embodiment would be modified by providing the module within a suitable enclosure, and locating the module in such a manner that feeds from a number of metering or customer interface units 35-36 are available to the module. For example, in a case where a single non-communication utility is involved, such as power, a module servicing a plurality of proximate customers would be located at a distribution node from which power is distributed to individual customers. This embodiment may limit the number of different utilities serviced by the module to the number of such utilities sharing the distribution node.

It will be understood by those familiar with the art that these illustrative examples are the application of the objects of this patent, the applications of which are not limited to these illustrative applications.

It is also recognized that other equivalents, alternatives, and modifications aside from those expressly stated by reference to the preferred and alternative embodiment may be practiced without departing from the scope of the invention as described herein and as set out in the claims.

The embodiments of the invention in which an exclusive property or privilege is claimed are defined as follows:

1. A customer utilities interface apparatus comprising a module associated with customer premises, said apparatus being adapted to receive utility information relating to the delivery of a non-communication utility to customer premises and to communicate said information over a passive optical network.

2. The customer utilities interface apparatus of claim 1 wherein said apparatus is further adapted to receive control information over said passive optical network for controlling the delivery of said utility to said customer premises.

3. The customer utilities interface apparatus of claim 1 wherein said apparatus is retrofitted to an electric power meter wall box at said customer premises.

4. The customer utilities interface apparatus of claim 3 wherein said apparatus is adapted to collect and transmit, over said passive optical network, utility delivery information for a plurality of utilities delivered to said customer premises, at least one of which is a non-communication utility.

5. Customer utilities interface apparatus for facilitating the collection and communication of commodity-related information at customer premises, comprising:
an optical fiber transducer for connecting said apparatus to a passive optical network fiber;
a network element for facilitating communication between said apparatus and a passive optical network;
at least one interface element for interfacing said apparatus with an electromagnetic signal associated with a non-communication utility supplied to said customer premises, said utility being a metered utility; and,
means for conditioning and transmitting said electromagnetic signal over said fiber to said passive optical network.

6. The customer utilities interface apparatus as in claim 5 wherein:
said at least one interface element comprises a plurality of interface elements for interfacing said apparatus with a plurality of electromagnetic signals, each of said electromagnetic signals being associated with one of a plurality of utilities supplied to said customer premises, said plurality of utilities comprising at least one non-communication metered utility; and,
means for aggregating said plurality of electromagnetic signals and for transmitting them over said fiber to said passive optical network.

7. The customer utilities interface apparatus of claim 6 wherein said metered utility is selected from the group comprising power, gas, water, oil and sewage.

8. The customer utilities interface apparatus of claim 5 or 7 wherein said apparatus is housed in a wall-mounted power meter base.

9. The customer utilities interface apparatus of claim 6 further including means for parsing a data stream received from said fiber and allocating data from said data stream among said interface elements.

10. The customer utilities interface apparatus of claim 5 wherein said network element is a PON burst controller.

11. The customer utilities interface apparatus of claim 5 wherein said interface elements are elements selected from the group comprising signal conditioners, connectors or signal processors.

12. A method of installing the customer utilities interface apparatus of claim 1 or claim 6 at customer premises having an electric power wall box attached to a power cable supplying power to said customer premises, said wall box comprising a power meter base and a cover, said method comprising:
detaching said wall box from said power cable;
replacing said wall box with said apparatus, said apparatus further comprising:
an apparatus housing adapted to attach to said power cable;
a power meter; and,
a cover for viewing said power meter through said cover.

13. A method of installing the customer utilities interface apparatus of claim 1 or claim 6 at customer premises having an electric power wall box attached to a power cable supplying power to said customer premises, said wall box comprising a power meter base and a cover secured to said base by connection means, said method comprising:
disconnecting said connection means and removing said cover from said power meter base;
connecting to said connection means an apparatus housing in which said apparatus is housed; and,
connecting said cover to said apparatus housing.

14. A method of installing the customer utilities interface apparatus of claim 1 or claim 6 at customer premises having an electric power wall box attached to a power cable supplying power to said customer premises, said wall box comprising a power meter base and a cover secured to said base by connection means, said method comprising:
disconnecting said connection means and removing said cover from said power meter base; and,
connecting to said connection means an apparatus housing in which said apparatus is housed, said apparatus housing comprising a power meter display and a housing cover for viewing said power meter display through said cover.

15. A system for metering multiple commodities at each of a plurality of customer premises, comprising:
a passive optical network providing a communication facility between said plurality of customer premises and a hub;
a customer module at each of said customer premises;
a hub module at said hub;
said customer module and said hub module each having an optical fiber transducer for connecting said modules to a passive optical network fiber;
said customer module and said hub module each having a network element for facilitating communication with one another through said passive optical network; and,
said customer module comprising a plurality of interface elements for interfacing said apparatus with a plurality of electromagnetic signals, each of said electromagnetic signals being associated with one of a plurality of utilities supplied to said customer premises, including at least one non-communication utility.

16. The system of claim 15 wherein said customer module comprises means for conditioning and aggregating said electromagnetic signals and for transmitting them over said fiber to said passive optical network.

17. The system of claim 15 where said non-communication utility is a metered utility.

18. The system of claim 17 wherein said metered utility is selected from the group comprising power, gas, water, oil and sewage.

19. The system of claim 15 or 17 wherein said customer module is housed in a wall-mounted power meter base.

20. The system of claim 15 wherein said customer module further includes means for parsing a data stream received from said fiber and allocating data from said data stream among said interface elements.

21. The system of claim 15 wherein said network element is a PON burst controller.

22. The system of claim 15 wherein said interface elements are elements selected from the group comprising signal conditioners, connectors or signal processors.

23. The customer interface apparatus of claim 3 wherein said fiber is routed such that disconnecting mating components of said electric power meter wall box severs or disconnects said fiber.

24. The customer interface apparatus of claim 23 wherein said optical fiber is threaded through an aperture in at least one of said mating components.

25. A utilities servicing module comprising:
an optical fiber transducer for connecting said apparatus to a fiber associated with a passive optical network and for converting optical signals received over said fiber into electrical signals;
a network element for facilitating communication between said apparatus and customer modules over said passive optical network;
wherein said utilities servicing module is adapted to parse said electrical signals into information relating to utilities used by each of a plurality of customer premises and to communicate said information to at least one utility supplier.

26. The utilities servicing module of claim 25, wherein said module is adapted to communicate control information from said at least one utility supplier to said customer premises over said passive optical network for controlling the delivery of said utility to a given customer premises.

27. The utilities servicing module of claim 26 wherein said control information relates to a function selected from the group comprising electrical power load shedding, reduction of utility service, increase in utility service and disconnection of the utility from the customer premises.
